(19) United States
(12) Patent Application Publication
(10) Pub. No.: US 2022/0180783 A1
(43) Pub. Date: Jun. 9, 2022

(54) SHIFT REGISTER UNIT, GATE DRIVE CIRCUIT AND DISPLAY DEVICE

(71) Applicants: Wuhan BOE Optoelectronics Technology Co.,Ltd., Wuhan (CN); BOE Technology Group Co., Ltd., Beijing (CN)

(72) Inventors: Peng JIANG, Beijing (CN); Ning ZHU, Beijing (CN); Maoxiu ZHOU, Beijing (US); Jiantao LIU, Beijing (CN); Yanping LIAO, Beijing (CN)

(21) Appl. No.: 17/362,675

(22) Filed: Jun. 29, 2021

(30) Foreign Application Priority Data
Dec. 3, 2020 (CN) 202011407302.2

(51) Int. Cl. G09G 3/20; G11C 19/28

(52) U.S. Cl. CPC G09G 3/20; G09G 2320/0223; G09G 2310/0286; G11C 19/287

(57) ABSTRACT

Disclosed are a shift register unit, a gate drive circuit and a display device. The shift register unit includes: the input circuit provides the signal of the input signal end to the first node; the reset circuit provides the signal of the first reference signal end to the first node in response to the signal of the reset signal end; the control circuit controls the signals of the first node and the second node, and the output circuit provides the signal of the clock signal end to the drive output end in response to the signal of the first node, and provides the signal of the second reference signal end to the drive output end in response to the signal of the second node; the signal of the first reference signal end and the signal of the second reference signal end are loaded independently of each other.

### CROSS-REFERENCE OF RELATED APPLICATIONS

The present application claims the priority of Chinese Patent Application No. 202011407302.2, filed with the China National Intellectual Property Administration on Dec. 3, 2020 and entitled “Shift Register Unit, Gate Drive Circuit and Display Device”, the entire content of which is hereby incorporated by reference.

### FIELD

The present disclosure relates to the technical field of display, in particular to a shift register unit, a gate drive circuit and a display device.

### BACKGROUND

With the rapid development of display technology, display devices are increasingly developed in the direction of high integration and low cost. The Gate Driver on Array, GOA, technology integrates Thin Film Transistor, TFT, gate drive circuit onto the array substrate of a display device to drive the display device. The gate drive circuit usually consists of multiple cascaded shift register units. However, the output of the shift register unit is unstable and can lead to display abnormalities.

### SUMMARY

Embodiments of the present disclosure provide a shift register unit, including an input circuit, a reset circuit, a control circuit and an output circuit;

the input circuit is configured to provide a signal of the input signal end to a first node in response to the signal of the input signal end;

the reset circuit is configured to provide a signal of a first reference signal end to the first node in response to a signal of a reset signal end;

the control circuit is configured to control a signal of the first node and a signal of a second node;

the output circuit is configured to provide a signal of a clock signal end to a drive output end in response to the signal of the first node, and provide a signal of a second reference signal end to the drive output end in response to the signal of the second node:

the signal of the first reference signal end and the signal of the second reference signal end are loaded independently of each other.

In some embodiments, the second node includes: a first sub-node and a second sub-node;

the control circuit includes a first sub-control circuit and a second sub-control circuit; the first sub-control circuit is configured to control the signal of the first node and a signal of the first sub-node; and the second sub-control circuit is configured to control the signal of the first node and a signal of the second sub-node;

the output circuit is configured to provide the signal of the second reference signal end to the drive output end in response to a signal of the first sub-node, and provide the signal of the second reference signal end to the drive output end in response to the signal of the second sub-node.

In some embodiments, the first sub-control circuit includes: a first transistor, a second transistor, a third transistor, a fourth transistor, and a fifth transistor;

a gate of the first transistor and a first electrode of the first transistor are electrically connected with a first control end, and a second electrode of the first transistor is electrically connected with a gate of the second transistor;

a first electrode of the second transistor is electrically connected with the first control end, and a second electrode of the second transistor is electrically connected with the first sub-node;

a gate of the third transistor is electrically connected with the first node, a first electrode of the third transistor is electrically connected with the first reference signal end, and a second electrode of the third transistor is electrically connected with the first sub-node;

a gate of the fourth transistor is electrically connected with the first node, a first electrode of the fourth transistor is electrically connected with the first reference signal end, and a second electrode of the fourth transistor is electrically connected with the gate of the second transistor; and

a gate of the fifth transistor is electrically connected with the first sub-node, a first electrode of the fifth transistor is electrically connected with the first reference signal end, and a second electrode of the fifth transistor is electrically connected with the first node.

In some embodiments, the first sub-control circuit further includes: a sixth transistor;

a gate of the sixth transistor is electrically connected with the input signal end, a first electrode of the sixth transistor is electrically connected with the first reference signal end, and a second electrode of the sixth transistor is electrically connected with the first sub-node.

In some embodiments, the second sub-control circuit includes: a seventh transistor, an eighth transistor, a ninth transistor, a tenth transistor, and an eleventh transistor;

a gate of the seventh transistor and a first electrode of the seventh transistor are both electrically connected with a first control end, and a second electrode of the seventh transistor is electrically connected with a gate of the eighth transistor;

a first electrode of the eighth transistor is electrically connected with the first control end, and a second electrode of the eighth transistor is electrically connected with the second sub-node;

a gate of the ninth transistor is electrically connected with the first node, a first electrode of the ninth transistor is electrically connected with the first reference signal end, and a second electrode of the ninth transistor is electrically connected with the second sub-node:

a gate of the tenth transistor is electrically connected with the first node, a first electrode of the tenth transistor is electrically connected with the first reference signal end, and a second electrode of the tenth transistor is electrically connected with the gate of the eighth transistor; and

a gate of the eleventh transistor is electrically connected with the second sub-node, a first electrode of the eleventh transistor is electrically connected with the first reference signal end, and a second electrode of the eleventh transistor is electrically connected with the first node.

In some embodiments, the second sub-control circuit further includes: a twelfth transistor;

a gate of the twelfth transistor is electrically connected with the input signal end, a first electrode of the twelfth transistor is electrically connected with the first reference signal end, and a second electrode of the twelfth transistor is electrically connected with the second sub-node.

In some embodiments, the output circuit includes: a storage capacitor, a thirteenth transistor, a fourteenth transistor, and a fifteenth transistor;

a gate of the thirteenth transistor is electrically connected with the first node, a first electrode of the thirteenth transistor is electrically connected with the clock signal end, and a second electrode of the thirteenth transistor is electrically connected with the drive output end;

a gate of the fourteenth transistor is electrically connected with the first sub-node, a first electrode of the fourteenth transistor is electrically connected with the second reference signal end, and a second electrode of the fourteenth transistor is electrically connected with the drive output end;

a gate of the fifteenth transistor is electrically connected with the second sub-node, a first electrode of the fifteenth transistor is electrically connected with the second reference signal end, and a second electrode of the fifteenth transistor is electrically connected with the drive output end; and

a first electrode of the storage capacitor is electrically connected with the first node, and the second electrode of the storage capacitor is electrically connected with the drive output end.

In some embodiments, the input circuit includes a sixteenth transistor; and

a gate of the sixteenth transistor and a first electrode of the sixteenth transistor are both electrically connected with the input signal end, and a second electrode of the sixteenth transistor is electrically connected with the first node.

In some embodiments, the reset circuit includes: a seventeenth transistor; and

a gate of the seventeenth transistor is electrically connected with the reset signal end, a first electrode of the seventeenth transistor is electrically connected with the first reference signal end, and a second electrode of the seventeenth transistor is electrically connected with the first node.

In some embodiments, the signal of the first reference signal end and the signal of the second reference signal end are provided with a same voltage.

In some embodiments, the shift register unit further includes: an eighteenth transistor; a gate of the eighteenth transistor is electrically connected with a first frame reset signal end, a first electrode of the eighteenth transistor is electrically connected with the first reference signal end, and a second electrode of the eighteenth transistor is electrically connected with the first node; and/or,

a nineteenth transistor; wherein a gate of the nineteenth transistor is electrically connected with a second frame reset signal end, a first electrode of the nineteenth transistor is electrically connected with the second reference signal end, and a second electrode of the nineteenth transistor is electrically connected with the drive output end.

A gate drive circuit provided in embodiments of the present disclosure includes a plurality of cascaded shift register units;

the input signal end of a first-stage shift register unit is electrically connected with a frame trigger signal end;

for each two adjacent stages of shift register units, a input signal end of a lower-stage shift register unit is electrically connected with a drive output end of a upper-stage shift register unit, and a reset signal end of the upper-stage shift register unit is electrically connected with a drive output end of the lower-stage shift register unit.

Embodiments of the present disclosure provide a display device, including the above gate drive circuit.

In some embodiments, the display device further includes: a first reference signal line and a second reference signal line, arranged at intervals with each other;

a first reference terminal, electrically connected with the first reference signal line; and

a second reference terminal electrically connected with the second reference signal line;

the first reference signal end of the shift register unit in the gate drive circuit is electrically connected with the first reference signal line;

the second reference signal end of the shift register unit in the gate drive circuit is electrically connected with the second reference signal line.

In some embodiments, the display device further includes: a driver chip; and

the driver chip is bonded to the first reference terminal and the second reference terminal, respectively, and the driver chip is configured to load a signal to the first reference signal end of the shift register unit in the gate drive circuit via the first reference terminal, and load a signal to the second reference signal end of the shift register unit in the gate drive circuit via the second reference terminal.

### BRIEF DESCRIPTION OF THE DRAWINGS

FIG. 1 is a schematic diagram of some structures of a shift register unit in embodiments of the present disclosure.

FIG. 2 is another schematic diagram of some other structures of a shift register unit in embodiments of the present disclosure.

FIG. 3 is a schematic diagram of some structures of a shift register unit in embodiments of the present disclosure.

FIG. 4 is some signal timing diagrams in embodiments of the present disclosure.

FIG. 5 is a schematic diagram of some other structures of a shift register unit in embodiments of the present disclosure.

FIG. 6 is some other signal timing diagrams in embodiments of the present disclosure.

FIG. 7 is a structural schematic diagram of a gate drive circuit in embodiments of the present disclosure.

### DETAILED DESCRIPTION OF THE EMBODIMENTS

In order to make the objectives, technical solutions, and advantages of embodiments of the present disclosure clearer, the technical solutions of embodiments of the present disclosure will be described clearly and completely below in combination with accompanying drawings of embodiments of the present disclosure. Apparently, the described embodiments are only a part but not all of embodiments of the present disclosure. Moreover, without conflict, embodiments and features in embodiments of the present disclosure can be combined with each other. Based upon the described embodiments of the present disclosure, all of the other embodiments obtained by those skilled in the art without any creative effort shall all fall within the protection scope of the present disclosure.

Unless otherwise defined, technical or scientific terms used in the present disclosure shall have the ordinary meanings as understood by those skilled in the art to which the present disclosure pertains. The terms “first” “second” and the like, as used in the present disclosure, do not indicate any order, number, or importance, but are merely used to distinguish between different components. The words “including” or “containing” and the like are intended to mean that the component or object appearing before the word covers the component or object appearing after the word and its equivalent, and does not exclude other components or objects. Similar words such as “connection” or “connected” are not limited to physical or mechanical connections, but may include electrical connection, whether direct or indirect connection.

It is noted that the size and shape of the figures in the accompanying drawings do not reflect true proportions, and are only intended to exemplarily illustrate the contents of the present disclosure. Moreover, the same or similar reference numerals throughout the text indicate the same or similar components or components having the same or similar functions.

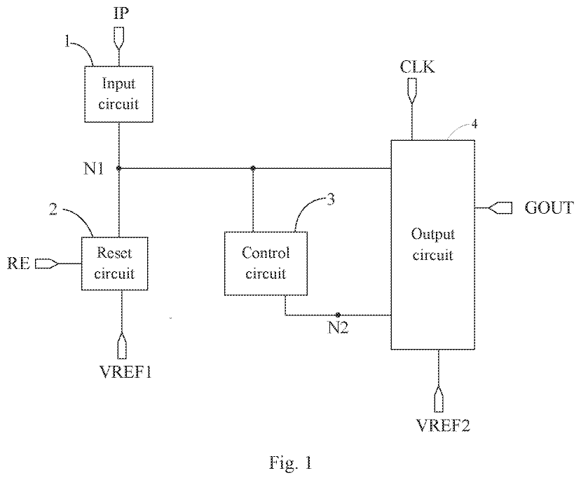

Embodiments of the present disclosure provide a shift register unit, as shown in FIG. 1, the shift register unit may include: an input circuit 1, a reset circuit 2, a control circuit 3 and an output circuit 4;

the input circuit 1 is configured to provide a signal of the input signal end IP to a first node N1 in response to the signal of the input signal end IP;

the reset circuit 2 is configured to provide a signal of a first reference signal end VREF1 to the first node N1 in response to a signal of a reset signal end RE;

the control circuit 3 is configured to control a signal of the first node N1 and a signal of a second node N2;

the output circuit 4 is configured to provide a signal of a clock signal end CLK to a drive output end GOUT in response to a signal of the first node N1, and provide a signal of a second reference signal end VREF2 to the drive output end GOUT in response to the signal of the second node N2;

the signal of the first reference signal end VREF1 and the signal of the second reference signal end VREF2 are loaded independently of each other.

In the above shift register unit provided in embodiments of the present disclosure, the signal of the input signal end IP can be provided to the first node N1 by the input circuit 1 in response to a signal of the input signal end IP. The signal of the first reference signal end VREF1 can be provided to the first node N1 by the reset circuit 2 in response to a signal of the reset signal end RE. The signal of the first node N1 and the signal of the second node N2 can be controlled through the control circuit 3. The signal of the clock signal end CLK can be provided to the drive output end GOUT by the output circuit 4 in response to the signal of the first node N1, and the signal of the second reference signal end VREF2 can be provided to the drive output end GOUT by the output circuit 4 in response to the signal of the second node N2. The signals of the first reference signal end VREF1 and the signals of the second reference signal end VREF2 are loaded independently of each other. In this way, the signal can be transmitted to the first reference signal end VREF1 and to the second reference signal end VREF2 respectively using mutually independent signal. Moreover, since the signal line transmitting the signal to the second reference signal end VREF2 is only electrically connected with the output circuit 4, the load on the signal line transmitting the signal to the second reference signal end VREF2 can be reduced, thereby reducing the RC delay (delay) of the signal line transmitting the signal to the second reference signal end VREF2. In this way, the voltage stability of the signal loaded at the second reference signal end VREF2 may be improved, thereby improving the stability of the signal output by the drive output end GOUT.

In some embodiments, the signal of the first reference signal end VREF1 and the signal of the second reference signal end VREF2 may be provided with a same voltage. Alternatively, the signal of the first reference signal end VREF1 and the signal of the second reference signal end VREF2 may be provided with different voltages. For example, the voltage of the signal of the first reference signal end VREF1 is greater than the voltage of the signal of the second reference signal end VREF2. Or the voltage of the signal of the first reference signal end VREF1 is less than the voltage of the signal of the second reference signal end VREF2.

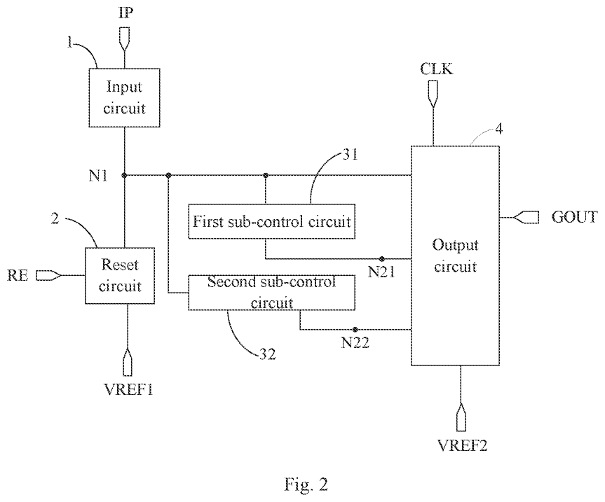

In some embodiments, as shown in FIG. 2, the second node N2 can include: a first sub-node N21 and a second sub-node N22. Moreover, the control circuit 3 includes a first sub-control circuit 31 and a second sub-control circuit 32; the first sub-control circuit 31 is configured to control signals of the first node N1 and the first sub-node N21; and the second sub-control circuit 32 is configured to control the signal of the first node N1 and the signal of the second sub-node N22. In addition, the output circuit 4 is configured to provide the signal of the second reference signal end VREF2 to the drive output end GOUT in response to the signal of the first sub-node N21, and provide the signal of the second reference signal end VREF2 to the drive output end GOUT in response to the signal of the second sub-node N22.

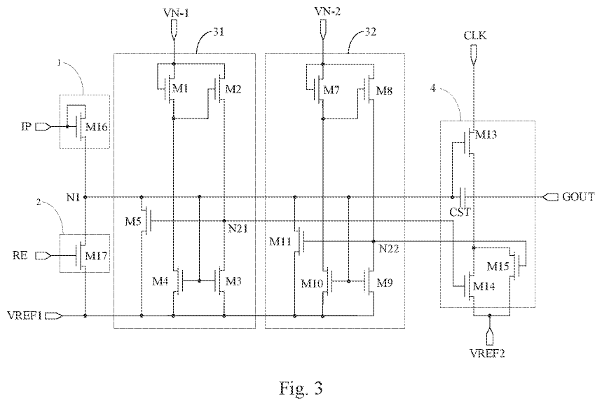

In some embodiments, as shown in FIG. 3, the first sub-control circuit 31 may include: a first transistor M1, a second transistor M2, a third transistor M3, a fourth transistor M4, and a fifth transistor M5:

the gate of the first transistor M1 and the first electrode of the first transistor M1 are both electrically connected with the first control end, and the second electrode of the first transistor M1 is electrically connected with the gate of the second transistor M2;

the first electrode of the second transistor M2 is electrically connected with the first control end, and the second electrode of the second transistor M2 is electrically connected with the first sub-node N21;

the gate of the third transistor M3 is electrically connected with the first node N1, the first electrode of the third transistor M3 is electrically connected with the first reference signal end VREF1, and the second electrode of the third transistor M3 is electrically connected with the first sub-node N21:

the gate of the fourth transistor M4 is electrically connected with the first node N1, the first electrode of the fourth transistor M4 is electrically connected with the first reference signal end VREF1, and the second electrode of the fourth transistor M4 is electrically connected with the gate of the second transistor M2; and

the gate of the fifth transistor M5 is electrically connected with the first sub-node N21, the first electrode of the fifth transistor M5 is electrically connected with the first reference signal end VREF1, and the second electrode of the fifth transistor M5 is electrically connected with the first node N1.

In some embodiments, as shown in FIG. 3, the second sub-control circuit 32 may include; a seventh transistor M7, an eighth transistor M8, a ninth transistor M9, a tenth transistor M10, and an eleventh transistor M11;

the gate of the seventh transistor M7 and the first electrode of the seventh transistor M7 are both electrically connected with the first control end, and the second electrode of the seventh transistor M7 is electrically connected with the gate of the eighth transistor M8:

the first electrode of the eighth transistor M8 is electrically connected with the first control end, and the second electrode of the eighth transistor M8 is electrically connected with the second sub-node N22:

the gate of the ninth transistor M9 is electrically connected with the first node N1, the first electrode of the ninth transistor M9 is electrically connected with the first reference signal end VREF1, and the second electrode of the ninth transistor M9 is electrically connected with the second sub-node N22;

the gate of the tenth transistor M10 is electrically connected with the first node N1, the first electrode of the tenth transistor M10 is electrically connected with the first reference signal end VREF1, and the second electrode of the tenth transistor M10 is electrically connected with the gate of the eighth transistor M8; and

the gate of the eleventh transistor M11 is electrically connected with the second sub-node N22, the first electrode of the eleventh transistor M11 is electrically connected with the first reference signal end VREF1, and the second electrode of the eleventh transistor M11 is electrically connected with the first node N1.

In some embodiments, as shown in FIG. 3, the output circuit 4 may include: a thirteenth transistor M13, a fourteenth transistor M14, and a fifteenth transistor M15;

the gate of the thirteenth transistor M13 is electrically connected with the first node N1, the first electrode of the thirteenth transistor M13 is electrically connected with the clock signal end CLK, and the second electrode of the thirteenth transistor M13 is electrically connected with the drive output end GOUT;

the gate of the fourteenth transistor M14 is electrically connected with the first sub-node N21, the first electrode of the fourteenth transistor M14 is electrically connected with the second reference signal end VREF2, and the second electrode of the fourteenth transistor M14 is electrically connected with the drive output end GOUT;

the gate of the fifteenth transistor M15 is electrically connected with the second sub-node N22, the first electrode of the fifteenth transistor M15 is electrically connected with the second reference signal end VREF2, and the second electrode of the fifteenth transistor M15 is electrically connected with the drive output end GOUT; and

the first electrode of the storage capacitor is electrically connected with the first node N1, and the second electrode of the storage capacitor is electrically connected with the drive output end GOUT.

In some embodiments, as shown in FIG. 3, the input circuit 1 may include a sixteenth transistor M16:

the gate and the first electrode of the sixteenth transistor M16 are both electrically connected with the input signal end IP, and the second electrode of the sixteenth transistor M16 is electrically connected with the first node N1.

In some embodiments, as shown in FIG. 3, the reset circuit 2 may include: a seventeenth transistor M17;

the gate of the seventeenth transistor M17 is electrically connected with the reset signal end RE, the first electrode of the seventeenth transistor M17 is electrically connected with the first reference signal end VREF1, and the second electrode of the seventeenth transistor M17 is electrically connected with the first node N1.

The above is only an example to illustrate the structure of the shift register unit provided in embodiments of the present disclosure, and in some embodiments, the structure of each of the above circuits is not limited to the above structure provided in embodiments of the present disclosure, but may also be other structures that are known to those skilled in the art, which is not limited herein.

In order to reduce the preparation process, in some embodiments, all the transistors may be N-type transistors as shown in FIG. 3. Moreover, the signal of the first reference signal end VREF1 may be a low level signal, and the signal of the second reference signal end VREF2 may also be a low level signal. Of course, in some embodiments, all the transistors may also be P-type transistors, which will not be limited herein.

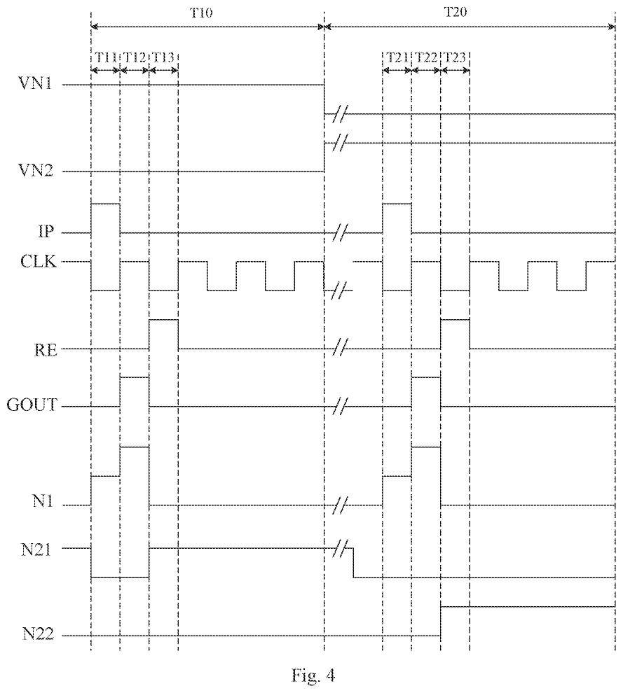

In some embodiments, the signal of the first control end VN1 and the signal of the second control end VN2 may be pulsed signals switched at high and low levels, respectively, moreover, the level of the first control end VN1 and the level of the second control end VN2 are opposite. For example, as shown in FIG. 4, in phase T10, the first control end VN1 is a high level signal and the second control end VN2 is a low level signal. In phase T20, the first control end VN1 is a low level signal and the second control end VN2 is a high level signal. Exemplarily, the maintenance duration of phase T10 may be the same as the maintenance duration of phase T20. In some embodiments, the maintenance duration of phase T10 and the maintenance duration of phase T20 are set to the duration of 1 display frame, the duration of multiple display frames, 2 s, 1 h, or 24 h, respectively, which is not limited herein.

In some embodiments, the signal of the first control end VN1 and the signal of the second control end VN2 may also be Direct Current, DC, signals, respectively. Moreover, when the first control end VN1 is loaded with a high level DC signal, the second control end VN2 is not loaded with a signal or is loaded with a low level DC signal. When the second control end is loaded with a high level DC signal, the first control end VN1 is not loaded with a signal or is loaded with a low level DC signal. For example, in phase T10, the first control end VN1 is a high level DC signal and the second control end VN2 is a low level DC signal. In phase T20, the first control end VN1 is a low level DC signal and the second control end VN2 is a high-level DC signal. Exemplarily, the maintenance duration of phase T10 can be the same as the maintenance duration of phase T20. For example, the maintenance duration of phase T10 and the maintenance duration of phase T20 are set to the duration of 1 display frame, the duration of multiple display frames, 2 s, 1 h, or 24 h, etc., respectively, which is not limited herein.

Phase T10 and phase T20 may be sequenced according to the actual application. For example, the working process in phase T10 may be executed first, followed by the working process in phase T20. Alternatively, the working process in phase T20 may be executed first, followed by the working process in phase T10.

The working process of the above shift register unit provided in embodiment of the present disclosure will be described below in detail with the shift register unit shown in FIG. 3 as an example and in combination with the signal timing diagram shown in FIG. 4. In the following description, 1 represents a high level signal and 0 represents a low level signal, here 1 and 0 represent their logic levels, only for the purpose of better explaining the working process of the above shift register unit provided in embodiment of the present disclosure, rather than the potential applied to the gate of each transistor during implementation.

Phases T10 and T20 of the signal timing diagram shown in FIG. 4 are selected. Moreover, the input phase T11, the reset phase T12, and the output phase T13 of the phase T10 are selected. The input phase T21, the reset phase T22, and the output phase T23 of the phase T20 are selected.

In phase T10, since the second control end VN2 is a low level signal, the seventh transistor M7 is cut off.

In the input stage T11, IP=1, CLK=0, RE=0.

Since RE=0, the seventeenth transistor M17 is cut off. Since IP=1, the sixteenth transistor M16 is conductive to provide a high level signal of the input signal end IP to the first node N1, so that the first node N1 is a high level signal, thereby controlling the third transistor M3, the fourth transistor M4, the ninth transistor M9, the tenth transistor M10, and the thirteenth transistor M13 to be conductive. The conductive fourth transistor M4 may provide a low level signal of the first reference signal end VREF1 to the gate of the second transistor M2, to control the second transistor M2 to cut off. The conductive third transistor M3 may provide the low level signal of the first reference signal end VREF1 to the first sub-node N21, such that the first sub-node N21 is a low level signal, to control both the fifth transistor M5 and the fourteenth transistor M14 to cut off. The conductive tenth transistor M10 may provide the low level signal of the first reference signal end VREF1 to the gate of the eighth transistor M8, to control the eighth transistor M8 to cut off. The conductive ninth transistor M9 may provide the low level signal of the first reference signal end VREF1 to the second sub-node N22, such that the second sub-node N22 is a low level signal, to control both the eleventh transistor M11 and the fifteenth transistor M15 to cut off. The conductive thirteenth transistor M13 can provide the low level signal of the clock signal end CLK to the drive signal output end GOUT, such that the drive signal output end GOUT outputs a low level signal.

In the output phase T12, IP=0, CLK=1, RE=0.

Since RE=0, the seventeenth transistor M17 is cut off. Since IP=0, the sixteenth transistor M16 is cut off. Therefore, the first node N1 is in a floating connection state. Due to the effect of the storage capacitor, the first node N1 can be kept as a high level signal. Since the first node N1 is a high level signal, the third transistor M3, the fourth transistor M4, the ninth transistor M9, the tenth transistor M10, and the thirteenth transistor M13 can be controlled to be conductive. The conductive fourth transistor M4 may provide a low level signal of the first reference signal end VREF1 to the gate of the second transistor M2, to control the second transistor M2 to cut off. The conductive third transistor M3 may provide the low level signal of the first reference signal end VREF1 to the first sub-node N21, such that the first sub-node N21 is a low level signal, to control both the fifth transistor M5 and the fourteenth transistor M14 to cut off. The conductive tenth transistor M10 may provide the low level signal of the first reference signal end VREF1 to the gate of the eighth transistor M8, to control the eighth transistor M8 to cut off. The conductive ninth transistor M9 may provide the low level signal of the first reference signal end VREF1 to the second sub-node N22, such that the second sub-node N22 is a low level signal, to control both the eleventh transistor M11 and the fifteenth transistor M15 to cut off.

The conductive thirteenth transistor M13 can provide the high level signal of the clock signal end CLK to the drive signal output end GOUT. Since the first node N1 is in a floating connection state, the first node N1 is further pulled up due to the effect of the storage capacitor, then the thirteenth transistor M13 can be fully conductive as much as possible, so that the high level signal of the clock signal end CLK can be provided to the drive signal output end GOUT with no voltage loss, and the drive signal output end GOUT outputs the high level signal.

In reset phase T13, IP=0, CLK=0, RE=1.

Since IP=0, the sixteenth transistor M16 is cut off. Since RE=1, the seventeenth transistor M17 is conductive, to provide a low level signal of the first reference signal end VREF1 to the first node N1, such that the first node N1 is a low level signal, thereby controlling the third transistor M3, the fourth transistor M4, the ninth transistor M9, the tenth transistor M10, and the thirteenth transistor M13 to cut off. Moreover, the second sub-node N22 is kept as a low level signal, to control the eleventh transistor M11 and the fifteenth transistor M15 to cut off.

The first transistor M1 is conductive under the control of the high level signal of the first control end VN1, to provide the high level signal of the first control end VN1 to the gate of the second transistor M2, thereby controlling the second transistor M2 to be conductive. The conductive second transistor M2 may provide the high level signal of the first control end VN1 to the first sub-node N21, such that the first sub-node N21 is a high level signal, to control both the fifth transistor M5 and the fourteenth transistor M14 to be conductive. The conductive fifth transistor M5 may provide a low level signal of the first reference signal end VREF1 to the first node N1, such that the first node N1 is further a low level signal. The conductive fourteenth transistor M14 may provide the low level signal of the second reference signal end VREF2 to the drive signal output end GOUT, such that the drive signal output end GOUT outputs a low level signal.

In phase T20, since the first control end VN1 is a low level signal, the first transistor M1 is cut off.

In the input phase T21, IP=1, CLK=0, RE=0.

Since RE=0, the seventeenth transistor M17 is cut off. Since IP=1, the sixteenth transistor M16 is conductive, to provide a high level signal of the input signal end IP to the first node N1, so that the first node N1 is a high level signal, thereby controlling the third transistor M3, the fourth transistor M4, the ninth transistor M9, the tenth transistor M10, and the thirteenth transistor M13 to be all conductive. The conductive fourth transistor M4 may provide a low level signal of the first reference signal end VREF1 to the gate of the second transistor M2 to control the second transistor M2 to cut off. The conductive third transistor M3 may provide the low level signal of the first reference signal end VREF1 to the first sub-node N21, such that the first sub-node N21 is a low level signal to control both the fifth transistor M5 and the fourteenth transistor M14 to cut off. The conductive tenth transistor M10 may provide the low level signal of the first reference signal end VREF1 to the gate of the eighth transistor M8, to control the eighth transistor M8 to cut off. The conductive ninth transistor M9 may provide the low level signal of the first reference signal end VREF1 to the second sub-node N22, such that the second sub-node N22 is a low level signal, to control both the eleventh transistor M11 and the fifteenth transistor M15 to cut off.

The conductive thirteenth transistor M13 can provide a low level signal of the clock signal end CLK to the drive signal output end GOUT, such that the drive signal output end GOUT outputs a low level signal.

In output phase T22, IP=0, CLK=1, RE=0.

Since RE=0, the seventeenth transistor M17 is cut off. Since IP=0, the sixteenth transistor M16 is cut off. Therefore, the first node N1 is in a floating connection state. Due to the effect of the storage capacitor, the first node N1 can be kept as a high level signal. Since the first node N1 is a high level signal, the third transistor M3, the fourth transistor M4, the ninth transistor M9, the tenth transistor M10, and the thirteenth transistor M13 are controlled to be conductive. The conductive fourth transistor M4 may provide a low level signal of the first reference signal end VREF1 to the gate of the second transistor M2, to control the second transistor M2 to cut off. The conductive third transistor M3 may provide the low level signal of the first reference signal end VREF1 to the first sub-node N21, such that the first sub-node N21 is a low level signal, to control both the fifth transistor M5 and the fourteenth transistor M14 to cut off. The conductive tenth transistor M10 may provide the low level signal of the first reference signal end VREF1 to the gate of the eighth transistor M8, to control the eighth transistor M8 to cut off. The conductive ninth transistor M9 may provide the low level signal of the first reference signal end VREF1 to the second sub-node N22, such that the second sub-node N22 is a low level signal, to control both the eleventh transistor M11 and the fifteenth transistor M15 to cut off.

The conductive thirteenth transistor M13 can provide the high level signal of the clock signal end CLK to the drive signal output end GOUT. Since the first node N1 is in a floating connection state, due to the effect of the storage capacitor, the first node N1 is further pulled up, then the thirteenth transistor M13 can be fully conductive as much as possible, so that the high level signal of the clock signal end CLK can be provided to the drive signal output end GOUT with no voltage loss, and the drive signal output end GOUT outputs the high level signal.

In reset phase T23, IP=0, CLK=0. RE=1.

Since IP=0, the sixteenth transistor M16 is cut off. Since RE=1, the seventeenth transistor M17 is conductive to provide a low level signal of the first reference signal end VREF1 to the first node N1, such that the first node N1 is a low level signal, thereby controlling the third transistor M3, the fourth transistor M4, the ninth transistor M9, the tenth transistor M10, and the thirteenth transistor M13 to cut off. Moreover, the first sub-node N21 is kept as a low level signal, to control both the fifth transistor M5 and the fourteenth transistor M14 to cut off.

The seventh transistor M7 is conductive under the control of the high level signal of the second control end VN2, to provide the high level signal of the second control end VN2 to the gate of the eighth transistor M8, thereby controlling the eighth transistor M8 to be conductive. The conductive eighth transistor M8 may provide the high level signal of the second control end VN2 to the second sub-node N22, such that the second sub-node N22 is a high level signal, to control both the eleventh transistor M11 and the fifteenth transistor M15 to be conductive. The conductive eleventh transistor M11 may provide a low level signal of the first reference signal end VREF1 to the first node N1, such that the first node N1 is further a low level signal. The conductive fifteenth transistor M15 may provide the low level signal of the second reference signal end VREF2 to the drive signal output end GOUT, such that the drive signal output end GOUT outputs a low level signal.

In summary, since the second reference signal end VREF2 is electrically connected with only the fourteenth transistor M14 and the fifteenth transistor M15, the signal line transmitting the signal to the second reference signal end VREF2 is also electrically connected with only the fourteenth transistor M14 and the fifteenth transistor M15, thereby leading to less load connected with the signal line transmitting the signal to the second reference signal end VREF2, and reducing the RC delay of the signal line for transmitting the signal to the second reference signal end VREF2.

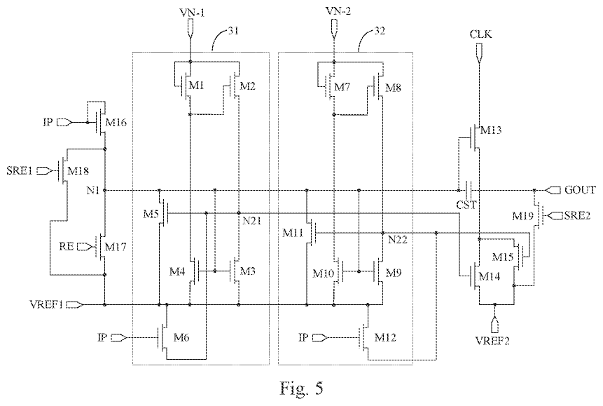

Embodiments of the present disclosure further provide some structural schematic diagrams of the shift register unit, as shown in FIG. 5, deformation is made aiming at the implementation of the above embodiments. Only the differences between the present embodiment and the above embodiments are described below, and their similarities are not repeated redundantly herein.

In some embodiments, as shown in FIG. 5, the first sub-control circuit 31 may further include: a sixth transistor M6:

a gate of the sixth transistor M6 is electrically connected with the input signal end IP, a first electrode of the sixth transistor M6 is electrically connected with the first reference signal end VREF1, and a second electrode of the sixth transistor M6 is electrically connected with the first sub-node N21.

In some embodiments, as shown in FIG. 5, the second sub-control circuit 32 may further include: a twelfth transistor M12;

the gate of the twelfth transistor M12 is electrically connected with the input signal end IP, the first electrode of the twelfth transistor M12 is electrically connected with the first reference signal end VREF1, and the second electrode of the twelfth transistor M12 is electrically connected with the second sub-node N22.

In some embodiments, as shown in FIG. 5, the shift register unit may further include: an eighteenth transistor M18;

a gate of the eighteenth transistor M18 is electrically connected with a first frame reset signal end RE, a first electrode of the eighteenth transistor M18 is electrically connected with a first reference signal end VREF1, and a second electrode of the eighteenth transistor M18 is electrically connected with a first node N1.

In some embodiments, as shown in FIG. 5, the shift register unit may further include: a nineteenth transistor M19:

the gate of the nineteenth transistor M19 is electrically connected with the second frame reset signal end RE, the first electrode of the nineteenth transistor M19 is electrically connected with the second reference signal end VREF2, and the second electrode of the nineteenth transistor M19 is electrically connected with the drive output end GOUT.

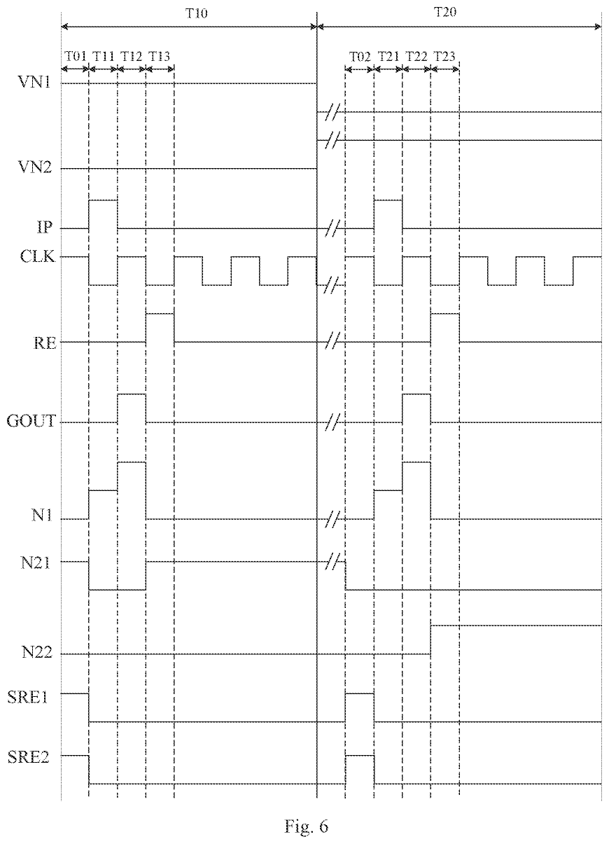

The working process of the above shift register unit provided in embodiments of the present disclosure will be described below with the shift register unit shown in FIG. 5 as an example and in combination with the signal timing diagram shown in FIG. 6. The corresponding working process in the present embodiment is partially the same as the working process of the shift register unit shown in FIG. 3, and only the contents of different working process will be described below.

In phase T10, before the input phase T11, a frame reset phase T01 may also be included. In the frame reset phase T01, the first frame reset signal end RE is a high level signal, and the eighteenth transistor M18 may be controlled to be conductive to provide a low level signal of the first reference signal end VREF1 to the first node N1, thereby pre-resetting the first node N1. Further, the noise at the drive output end GOUT can be further lowered. Moreover, the second frame reset signal end RE is a high level signal, which can control the nineteenth transistor M19 to be conductive to provide a low level signal of the second reference signal end VREF2 to the drive output end GOUT, thereby pre-resetting the drive output end GOUT, and the noise at the drive output end GOUT can be further lowered. Moreover, in the input stage T11, the sixth transistor M6 is conductive under the control of the high level signal of the input signal end IP, to provide the low level signal of the first reference signal end VREF1 to the first sub-node N21, so that the first sub-node N21 can be further a level signal, and the noise at the drive output end GOUT can be further lowered. The twelfth transistor M12 is conductive under the control of a high level signal of the input signal end IP, to provide a low level signal of the first reference signal end VREF1 to the second sub-node N22, so that the second sub-node N22 can be further made to be a low level signal, and the noise at the drive output end GOUT can be further lowered.

In phase T20, before the input phase T21, a frame reset phase T02 may also be included. In the frame reset phase T02, the first frame reset signal end RE is a high level signal, and the eighteenth transistor M18 may be controlled to be conductive to provide a low level signal of the first reference signal end VREF1 to the first node N1, thereby pre-resetting the first node N1. Further, the noise at the drive output end GOUT can be further lowered. Moreover, the second frame reset signal end RE is a high level signal, which can control the nineteenth transistor M19 to be conductive to provide a low level signal of the second reference signal end VREF2 to the drive output end GOUT, thereby pre-resetting the drive output end GOUT, and the noise at the drive output end GOUT can be further lowered. Moreover, in the input stage T11, the sixth transistor M6 is conductive under the control of the high level signal of the input signal end IP, to provide the low level signal of the first reference signal end VREF1 to the first sub-node N21, so that the first sub-node N21 can be further a level signal, and the noise at the drive output end GOUT can be further lowered. The twelfth transistor M12 is conductive under the control of a high level signal of the input signal end IP, to provide a low level signal of the first reference signal end VREF1 to the second sub-node N22, so that the second sub-node N22 can be further made to be a low level signal, and the noise at the drive output end GOUT can be further lowered.

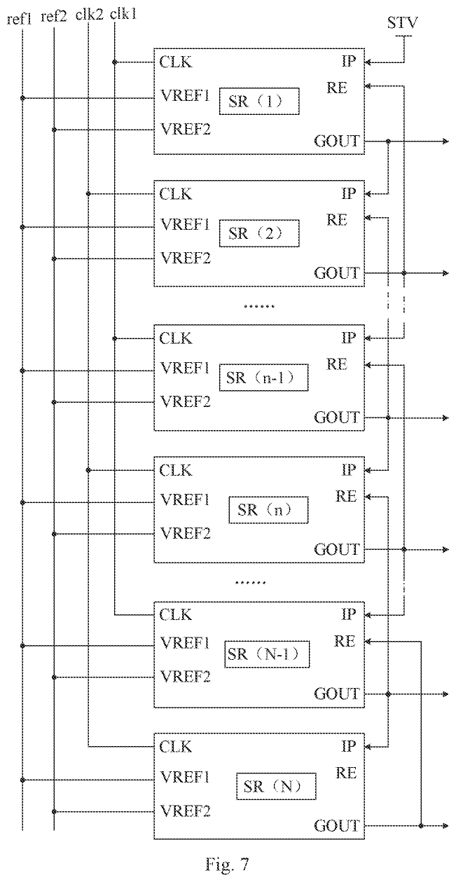

Embodiments of the present disclosure also provide a gate driving circuit, as shown in FIG. 7, including a plurality of cascaded shift register units provided in embodiments of the present disclosure: SR(1), SR(2) . . . SR(n−1), SR(n) . . . SR(N−1), SR(N) (a total of N shift register units, 1≤n≤N. and n and N are positive integers);

the input signal end IP of the first-stage shift register unit SR(1) is electrically connected with the frame trigger signal end STV;

for each two adjacent stages of shift register units, the input signal end IP of the lower-stage shift register unit SR(n) is electrically connected with the drive output end GOUT of the upper-stage shift register unit SR(n−1), and the reset signal end RE of the upper-stage shift register unit SR(n−1) is electrically connected with the drive output end GOUT of the lower-stage shift register unit SR(n).

Each shift register unit in the above gate drive circuit is functionally and structurally identical to the shift register units provided in embodiments of the present disclosure, and the same parts will not be repeated redundantly herein.

In the gate drive circuit provided in embodiments of the present disclosure, as shown in FIG. 7, the clock signal ends CLK of the odd-stage shift register units are all electrically connected with the same clock line clk1, and the clock signal ends CLK of the even-stage shift register units are all electrically connected with the same clock line clk2.

In the gate driving circuit provided in embodiments of the present disclosure, as shown in FIG. 7, a first reference signal end VREF1 of each stage of shift register unit is electrically connected with the same first reference signal line ref1. The second reference signal end VREF2 of each stage of shift register unit is electrically connected with the same second reference signal line ref2.

In some embodiments, when the shift register unit includes an eighteenth transistor M18, the first frame reset signal end RE of each stage of shift register unit may be electrically connected with the same first frame reset end. In this way, the first node N1 of each stage of shift register unit can be pre-reset at the same time.

In some embodiments, when the shift register unit includes a nineteenth transistor M19, the second frame reset signal end RE of each stage of shift register unit can be electrically connected with the same second frame reset end. In this way, the drive output end GOUT of each stage of shift register unit can be pre-reset at the same time.

Based on the same inventive concept, embodiments of the present disclosure further provide a display device including the above gate drive circuit provided in embodiments of the present disclosure. The display device solves the problem based on the similar principles as the aforementioned gate drive circuit, so for the implementation of the display device, please refer to the implementation of the aforementioned gate drive circuit, and the same parts will not be repeated redundantly herein.

In some embodiments, the display device may further include: a first reference signal line and a second reference signal line arranged at intervals with each other, a first reference terminal electrically connected with the first reference signal line, and a second reference terminal electrically connected with the second reference signal line; the first reference signal end VREF1 of the shift register unit in the gate driving circuit is electrically connected with the first reference signal line, and the second reference signal end VREF2 of the shift register unit in the gate driving circuit is electrically connected with the second reference signal line.

In some embodiments, the display device may further include: a driver chip; wherein the driver chip is bonded to the first reference terminal and the second reference terminal, respectively, and the driver chip is configured to load a signal to the first reference signal end VREF1 of the shift register unit in the gate drive circuit via the first reference terminal, and to load a signal to the second reference signal end VREF2 of the shift register unit in the gate drive circuit via the second reference terminal.

In some embodiments, the display device may be a cell phone, a tablet computer, a television, a display, a notebook computer, a digital photo frame, a navigator and any other products or components with a display function. The other essential components of the display device should be understood as necessary by those of ordinary skills in the art and are not described herein, nor should they be taken as a limitation to the present disclosure.

The present disclosure discloses a shift register unit, a gate drive circuit, and a display device, the shift register unit includes an input circuit, a reset circuit, a control circuit, and an output circuit. A signal of the input signal end may be provided to the first node by the input circuit in response to a signal of the input signal end. A signal of the first reference signal end can be provided to the first node by the reset circuit in response to a signal of the reset signal end. The signals of the first node and the second node can be controlled by the control circuit. The signal of the clock signal end can be provided to the drive output end by the output circuit in response to the signal of the first node, and the signal of the second reference signal end can be provided to the drive output end in response to the signal of the second node. Since the signals of the first reference signal end and the signals of the second reference signal end are loaded independently of each other, in this way, signals can be transmitted to the first reference signal end and to the second reference signal end respectively using mutually independent signals. Moreover, since the signal line transmitting the signal to the second reference signal end is only electrically connected with the output circuit, the load on the signal line transmitting the signal to the second reference signal end can be reduced, thereby reducing the RC delay of the signal line transmitting the signal to the second reference signal end. In this way, the voltage stability of the signal loaded at the second reference signal end may be improved, thereby improving the stability of the signal output by the drive output end.

Evidently, those skilled in the art can make various modifications and variations to the present disclosure without departing from the spirit and scope of the present disclosure. Accordingly, the present disclosure is also intended to encompass these modifications and variations thereto so long as the modifications and variations come into the scope of the claims appended to the disclosure and their equivalents.

What is claimed is:

1. A shift register unit, comprising:
an input circuit, configured to provide a signal of an input signal end to a first node in response to the signal of the input signal end;
a reset circuit, configured to provide a signal of a first reference signal end to the first node in response to a signal of a reset signal end;
a control circuit, configured to control a signal of the first node and a signal of a second node;
an output circuit, configured to provide a signal of a clock signal end to a drive output end in response to the signal of the first node, and provide a signal of a second reference signal end to the drive output end in response to the signal of the second node;
wherein the signal of the first reference signal end and the signal of the second reference signal end are loaded independently of each other.

2. The shift register unit of claim 1, wherein the second node comprises: a first sub-node and a second sub-node;
the control circuit comprises:
a first sub-control circuit, configured to control the signal of the first node and a signal of the first sub-node; and
a second sub-control circuit, configured to control the signal of the first node and a signal of the second sub-node:
wherein the output circuit is configured to provide the signal of the second reference signal end to the drive output end in response to the signal of the first sub-node, and provide the signal of the second reference signal end to the drive output end in response to the signal of the second sub-node.

3. The shift register unit of claim 2, wherein the first sub-control circuit comprises: a first transistor, a second transistor, a third transistor, a fourth transistor, and a fifth transistor;
wherein a gate of the first transistor and a first electrode of the first transistor are electrically connected with a first control end, and a second electrode of the first transistor is electrically connected with a gate of the second transistor;
a first electrode of the second transistor is electrically connected with the first control end, and a second electrode of the second transistor is electrically connected with the first sub-node;
a gate of the third transistor is electrically connected with the first node, a first electrode of the third transistor is electrically connected with the first reference signal end, and a second electrode of the third transistor is electrically connected with the first sub-node;
a gate of the fourth transistor is electrically connected with the first node, a first electrode of the fourth transistor is electrically connected with the first reference signal end, and a second electrode of the fourth transistor is electrically connected with the gate of the second transistor; and
a gate of the fifth transistor is electrically connected with the first sub-node, a first electrode of the fifth transistor is electrically connected with the first reference signal end, and a second electrode of the fifth transistor is electrically connected with the first node.

4. The shift register unit of claim 3, wherein the first sub-control circuit further comprises: a sixth transistor;
a gate of the sixth transistor is electrically connected with the input signal end, a first electrode of the sixth transistor is electrically connected with the first reference signal end, and a second electrode of the sixth transistor is electrically connected with the first sub-node.

5. The shift register unit of claim 2, wherein the second sub-control circuit comprises: a seventh transistor, an eighth transistor, a ninth transistor, a tenth transistor, and an eleventh transistor;
a gate of the seventh transistor and a first electrode of the seventh transistor are both electrically connected with a first control end, and a second electrode of the seventh transistor is electrically connected with a gate of the eighth transistor;
a first electrode of the eighth transistor is electrically connected with the first control end, and a second electrode of the eighth transistor is electrically connected with the second sub-node;
a gate of the ninth transistor is electrically connected with the first node, a first electrode of the ninth transistor is electrically connected with the first reference signal end, and a second electrode of the ninth transistor is electrically connected with the second sub-node;
a gate of the tenth transistor is electrically connected with the first node, a first electrode of the tenth transistor is electrically connected with the first reference signal end, and a second electrode of the tenth transistor is electrically connected with the gate of the eighth transistor; and
a gate of the eleventh transistor is electrically connected with the second sub-node, a first electrode of the eleventh transistor is electrically connected with the first reference signal end, and a second electrode of the eleventh transistor is electrically connected with the first node.

6. The shift register unit of claim 5, wherein the second sub-control circuit further comprises: a twelfth transistor;
a gate of the twelfth transistor is electrically connected with the input signal end, a first electrode of the twelfth transistor is electrically connected with the first reference signal end, and a second electrode of the twelfth transistor is electrically connected with the second sub-node.

7. The shift register unit of claim 2, wherein the output circuit comprises: a storage capacitor, a thirteenth transistor, a fourteenth transistor, and a fifteenth transistor;
a gate of the thirteenth transistor is electrically connected with the first node, a first electrode of the thirteenth transistor is electrically connected with the clock signal end, and a second electrode of the thirteenth transistor is electrically connected with the drive output end;
a gate of the fourteenth transistor is electrically connected with the first sub-node, a first electrode of the fourteenth transistor is electrically connected with the second reference signal end, and a second electrode of the fourteenth transistor is electrically connected with the drive output end;
a gate of the fifteenth transistor is electrically connected with the second sub-node, a first electrode of the fifteenth transistor is electrically connected with the second reference signal end, and a second electrode of the fifteenth transistor is electrically connected with the drive output end; and
a first electrode of the storage capacitor is electrically connected with the first node, and a second electrode of the storage capacitor is electrically connected with the drive output end.

8. The shift register unit of claim 1, wherein the input circuit comprises a sixteenth transistor, and
a gate of the sixteenth transistor and a first electrode of the sixteenth transistor are both electrically connected with the input signal end, and a second electrode of the sixteenth transistor is electrically connected with the first node.

9. The shift register unit of claim 1, wherein the reset circuit comprises: a seventeenth transistor; and
a gate of the seventeenth transistor is electrically connected with the reset signal end, a first electrode of the seventeenth transistor is electrically connected with the first reference signal end, and a second electrode of the seventeenth transistor is electrically connected with the first node.

10. The shift register unit of claim 1, wherein the signal of the first reference signal end and the signal of the second reference signal end are provided with a same voltage.

11. The shift register unit of claim 1, wherein the shift register unit further comprises:
an eighteenth transistor; wherein a gate of the eighteenth transistor is electrically connected with a first frame reset signal end, a first electrode of the eighteenth transistor is electrically connected with the first reference signal end, and a second electrode of the eighteenth transistor is electrically connected with the first node; and/or,
a nineteenth transistor; wherein a gate of the nineteenth transistor is electrically connected with a second frame reset signal end, a first electrode of the nineteenth transistor is electrically connected with the second reference signal end, and a second electrode of the nineteenth transistor is electrically connected with the drive output end.

12. A gate drive circuit, comprising a plurality of cascaded shift register units of claim 1;
the input signal end of a first-stage shift register unit is electrically connected with a frame trigger signal end;
for each two adjacent stages of shift register units, a input signal end of a lower-stage shift register unit is electrically connected with a drive output end of a upper-stage shift register unit, and a reset signal end of the upper-stage shift register unit is electrically connected with a drive output end of the lower-stage shift register unit.

13. The gate drive circuit of claim 12, wherein the second node comprises: a first sub-node and a second sub-node;
the control circuit comprises:
a first sub-control circuit, configured to control the signal of the first node and a signal of the first sub-node; and
a second sub-control circuit, configured to control the signal of the first node and a signal of the second sub-node; and
wherein the output circuit is configured to provide the signal of the second reference signal end to the drive output end in response to the signal of the first sub-node, and provide the signal of the second reference signal end to the drive output end in response to the signal of the second sub-node.

14. The gate drive circuit of claim 13, wherein the first sub-control circuit comprises: a first transistor, a second transistor, a third transistor, a fourth transistor, and a fifth transistor:
wherein a gate of the first transistor and a first electrode of the first transistor are both electrically connected with a first control end, and a second electrode of the first transistor is electrically connected with a gate of the second transistor:
a first electrode of the second transistor is electrically connected with the first control end, and a second electrode of the second transistor is electrically connected with the first sub-node;
a gate of the third transistor is electrically connected with the first node, a first electrode of the third transistor is electrically connected with the first reference signal end, and a second electrode of the third transistor is electrically connected with the first sub-node;
a gate of the fourth transistor is electrically connected with the first node, a first electrode of the fourth transistor is electrically connected with the first reference signal end, and a second electrode of the fourth transistor is electrically connected with the gate of the second transistor; and
a gate of the fifth transistor is electrically connected with the first sub-node, a first electrode of the fifth transistor is electrically connected with the first reference signal end, and a second electrode of the fifth transistor is electrically connected with the first node.

15. The gate drive circuit of claim 14, wherein the first sub-control circuit further comprises: a sixth transistor;
a gate of the sixth transistor is electrically connected with the input signal end, a first electrode of the sixth transistor is electrically connected with the first reference signal end, and a second electrode of the sixth transistor is electrically connected with the first sub-node.

16. The gate drive circuit of claim 13, wherein the second sub-control circuit comprises: a seventh transistor, an eighth transistor, a ninth transistor, a tenth transistor, and an eleventh transistor;
a gate of the seventh transistor and a first electrode of the seventh transistor are both electrically connected with a first control end, and a second electrode of the seventh transistor is electrically connected with a gate of the eighth transistor,
a first electrode of the eighth transistor is electrically connected with the first control end, and a second electrode of the eighth transistor is electrically connected with the second sub-node:
a gate of the ninth transistor is electrically connected with the first node, a first electrode of the ninth transistor is electrically connected with the first reference signal end, and a second electrode of the ninth transistor is electrically connected with the second sub-node;
a gate of the tenth transistor is electrically connected with the first node, a first electrode of the tenth transistor is electrically connected with the first reference signal end, and a second electrode of the tenth transistor is electrically connected with the gate of the eighth transistor; and
a gate of the eleventh transistor is electrically connected with the second sub-node, a first electrode of the eleventh transistor is electrically connected with the first reference signal end, and a second electrode of the eleventh transistor is electrically connected with the first node.

17. The gate drive circuit of claim 16 wherein the second sub-control circuit further comprises: a twelfth transistor:
a gate of the twelfth transistor is electrically connected with the input signal end, a first electrode of the twelfth transistor is electrically connected with the first reference signal end, and a second electrode of the twelfth transistor is electrically connected with the second sub-node.

18. A display device, comprising the gate drive circuit of claim 12.

19. The display device of claim 18, wherein the display device further comprises:
a first reference signal line and a second reference signal line, arranged at intervals with each other,
a first reference terminal, electrically connected with the first reference signal line; and
a second reference terminal, electrically connected with the second reference signal line:
wherein the first reference signal end of the shift register unit in the gate drive circuit is electrically connected with the first reference signal line;
the second reference signal end of the shift register unit in the gate drive circuit is electrically connected with the second reference signal line.

20. The display device of claim 19, wherein the display device further comprises: a driver chip:
wherein the driver chip is bonded to the first reference terminal and the second reference terminal, respectively; and
the driver chip is configured to load a signal to the first reference signal end of the shift register unit in the gate drive circuit via the first reference terminal, and load a signal to the second reference signal end of the shift register unit in the gate drive circuit via the second reference terminal signal.
